(19) United States
(12) Patent Application Publication
(10) Pub. No.: US 2023/0327048 A1
(43) Pub. Date: Oct. 12, 2023

(54) LIGHT-EMITTING DEVICE

(71) Applicant: EPISTAR CORPORATION, Hsinchu (TW)

(72) Inventors: Chao-Hsing Chen, Hsinchu (TW); Yi-Hung Lin, Hsinchu (TW); Chien-Ya Hung, Hsinchu (TW)

(21) Appl. No.: 18/296,154

(22) Filed: Apr. 5, 2023

(30) Foreign Application Priority Data
Apr. 6, 2022 (TW) 111113123

(51) Int. Cl. H01L 33/38; H01L 33/20

(52) U.S. Cl. CPC H01L 33/38; H01L 33/20

(57) ABSTRACT

A light-emitting device includes a substrate; a first semiconductor layer and a semiconductor platform disposed on the first semiconductor layer, wherein the semiconductor platform includes a second semiconductor layer and an active layer between the first semiconductor layer and the second semiconductor layer; a plurality of openings passing through the semiconductor platform to uncover the first semiconductor layer; a plurality of first electrodes and a plurality of first electrode pads on the first semiconductor layer in the plurality of openings and not covering the semiconductor platform; a second electrode and a second electrode pad on the second semiconductor layer and not covering the first semiconductor layer in the plurality of openings, wherein a first surface of the plurality of first electrode pads is higher than a second surface of the second electrode pad, and a step difference between the first surface and the second surface is less than 2 μm.

### CROSS-REFERENCE TO RELATED APPLICATIONS

This disclosure claims the right of priority of TW Application No. 111113123 filed on Apr. 6, 2022, and the content of which is hereby incorporated by reference in its entirety.

### BACKGROUND

### Technical Field

The present disclosure relates to a light-emitting device, and in particular to a flip-chip light-emitting device comprising a plurality of first electrode pads and a second electrode pad.

### Description of the Related Art

Light-emitting diode (LED) is a solid-state semiconductor light-emitting device, which has the advantages of low power consumption, low heat generation, long lifetime, shockproof, small size, high response speed and good optical-electrical characteristics, such as stable emission wavelength. Therefore, light-emitting diodes have been widely applied in household appliances, equipment indicator lights, and optoelectronic products, and so forth.

### SUMMARY

A light-emitting device including a substrate; a first semiconductor layer and a semiconductor platform disposed on the first semiconductor layer, wherein the semiconductor platform includes a second semiconductor layer and an active layer between the first semiconductor layer and the second semiconductor layer; a plurality of openings passing through the semiconductor platform to uncover the first semiconductor layer; a plurality of first electrodes located on the first semiconductor layer in the plurality of openings and not covering the semiconductor platform; a second electrode on the second semiconductor layer and not covering the first semiconductor layer in the plurality of openings; a plurality of first electrode pads located on the first semiconductor layer in the plurality of openings and not covering the semiconductor platform; and a second electrode pad located on the semiconductor platform and not covering the first semiconductor layer in the plurality of openings, wherein a first surface of the plurality of first electrode pads is higher than a second surface of the second electrode pad, and a step difference between the first surface and the second surface is less than 2 μm.

### BRIEF DESCRIPTION OF THE DRAWINGS

FIG. 1 is a cross-sectional view of a light-emitting device 1 in accordance with an embodiment of the present disclosure.

FIG. 2A to FIG. 2C are top views of the light-emitting devices 1a-1c in accordance with embodiments of the present disclosure.

FIG. 3A to FIG. 3D are top views of the light-emitting devices 1d-1g in accordance with embodiments of the present disclosure.

FIG. 4 is a partial cross-sectional view of the light-emitting apparatus 2 in accordance with an embodiment of the present disclosure.

FIG. 5A is a top view of a mount substrate 20a in accordance with an embodiment of the present disclosure.

FIG. 5B is a top view of the light-emitting apparatus 2a in accordance with an embodiment of the present disclosure.

FIG. 6A is a top view of a mount substrate 20b in accordance with an embodiment of the present disclosure.

FIG. 6B is a top view of the light-emitting apparatus 2b in accordance with an embodiment of the present disclosure.

FIG. 7A is a top view of a mount substrate 20c in accordance with an embodiment of the present disclosure.

FIG. 7B is a top view of the light-emitting apparatus 2c in accordance with an embodiment of the present disclosure.

FIG. 8 is a schematic view of the light-emitting apparatus 3 in accordance with an embodiment of the present disclosure.

FIG. 9 is a partial cross-sectional view of the light-emitting apparatus 3 in accordance with an embodiment of the present disclosure.

FIG. 10 is a schematic view of the light-emitting apparatus 4 in accordance with an embodiment of the present disclosure.

FIG. 11 is a schematic view of the light-emitting apparatus 5 in accordance with an embodiment of the present disclosure.

### DETAILED DESCRIPTION OF THE EMBODIMENTS

In order to make the description of the present disclosure more detailed and complete, please refer to the description of the following embodiments with relevant figures. The embodiments shown below are for exemplifying the light-emitting device of the present disclosure, and the present disclosure is not limited to the following embodiments. In addition, the scope of the present disclosure is not limited thereto in the case that the dimensions, materials, shapes, relative arrangements, and so forth, of the constituent parts described in the embodiments of the present disclosure are not limited, which are merely for illustration. In addition, other layers/structures or steps may be incorporated in the following embodiments. For example, a description of “forming a second layer/structure on a first layer/structure” may comprise an embodiment where the first layer/structure directly contacts the second layer/structure, or an embodiment where the first layer/structure indirectly contacts the second layer/structure, namely other layers/structures exist between the first layer/structure and the second layer/structure. In addition, the spatial relative relationship between the first layer/structure and the second layer/structure may be varied depending on the operation or use of the apparatus. The first layer/structure itself is not limited to a single layer or a single structure; the first layer may include a plurality of sub-layers, and the first structure may include a plurality of sub-structures. Furthermore, the sizes or positional relationships, and so forth, of the components shown in each of the figures may be enlarged for the sake of clarity. Furthermore, in the following description, in order to appropriately omit the detailed description, identical names and designations are used for the same or similar components.

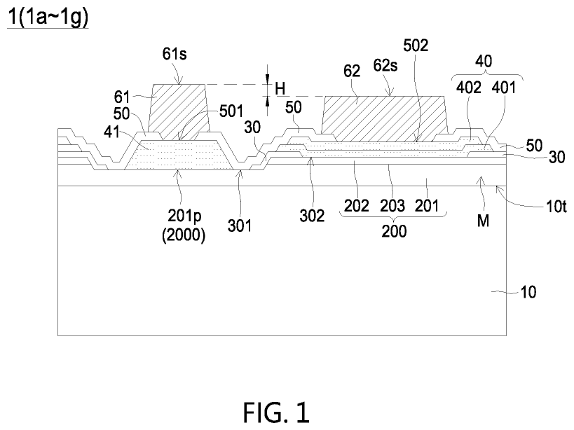

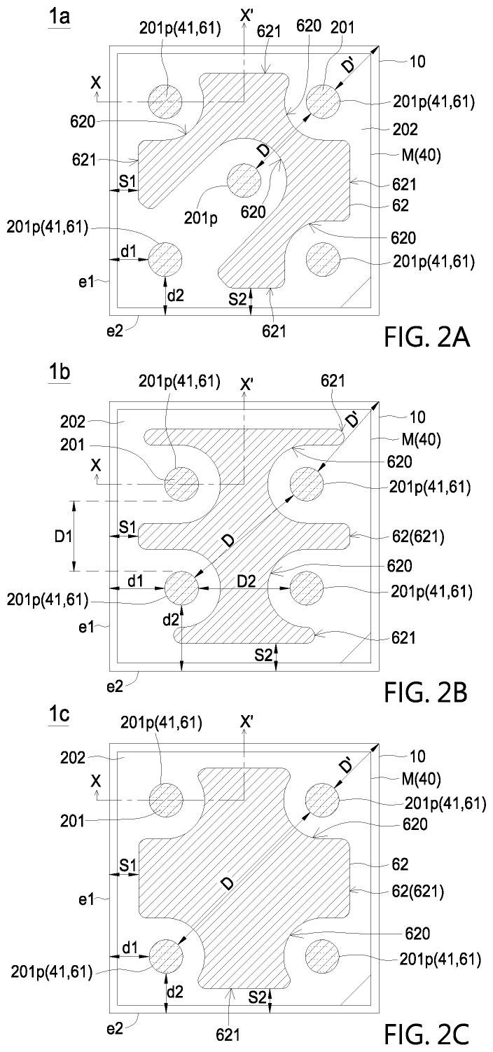

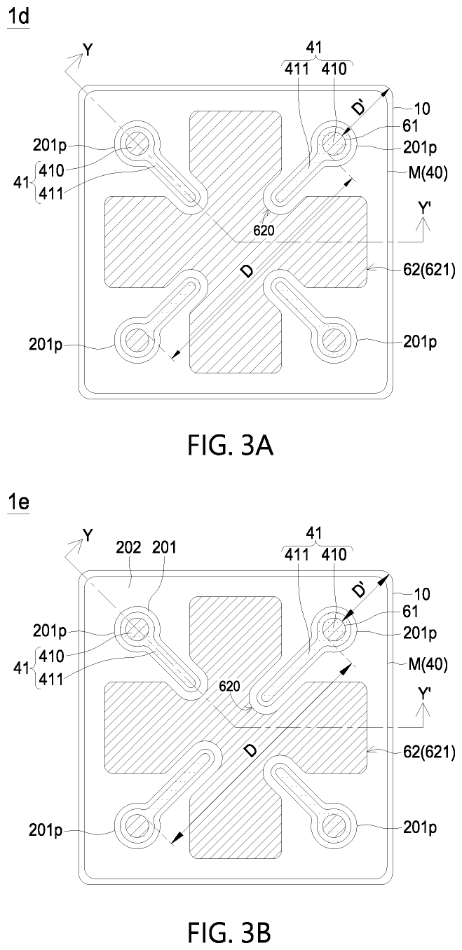

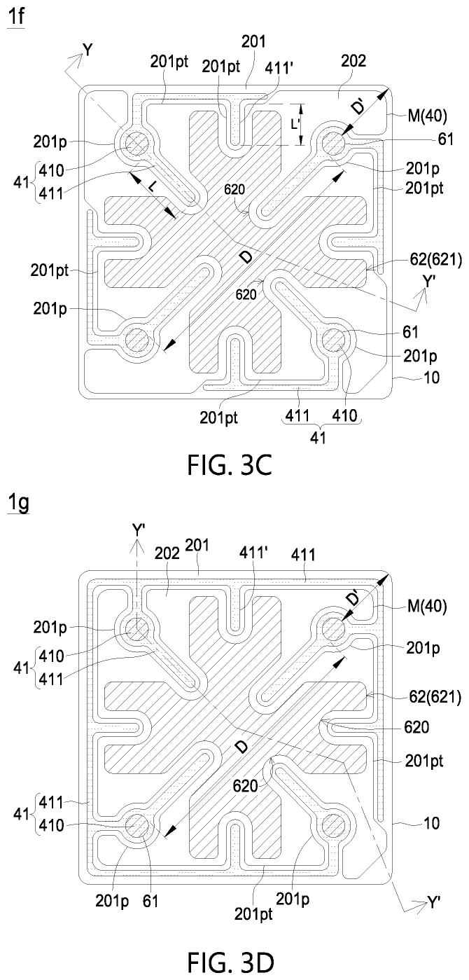

FIG. 1 is a cross-sectional view of a light-emitting device 1 in accordance with an embodiment of the present disclosure. FIG. 2A to FIG. 2C are top views of light-emitting devices 1a-1c in accordance with embodiments of the present disclosure. FIG. 3A to FIG. 3D are top views of light-emitting devices 1d-1g in accordance with embodiments of the present disclosure. The cross-sectional view of the light-emitting device 1 in FIG. 1 is a cross-sectional view along a line X-X′ in any of FIG. 2A to FIG. 2C or along a line Y-Y′ in any of FIG. 3A to FIG. 3D.

As shown in FIG. 1, the light-emitting device 1 or each of 1a-1g includes a substrate 10; a semiconductor stack 200 including a first semiconductor layer 201; a semiconductor platform M located on the first semiconductor layer 201 and including a second semiconductor layer 202 and an active layer 203 located between the first semiconductor layer 201 and the second semiconductor layer 202; an opening 2000 passing through the semiconductor platform M to expose the first semiconductor layer 201 and to form an exposed portions 201p of the first semiconductor layer 201; a first electrode 41 located in the exposed portion 201p of the first semiconductor layer 201 and not covering the semiconductor platform M; a second electrode 40 located on the semiconductor platform M and not covering the exposed portion 201p of the first semiconductor layer 201; a first electrode pad 61 located on the first electrode 41 and not covering the semiconductor platform M; and a second electrode pad 62 located on the second electrode 40 and not covering the exposed portion 201p of the first semiconductor layer 201, wherein a first surface 61s of the first electrode pad 61 is higher than a second surface 62s of the second electrode pad 62, and a step difference H between the first surface 61s and the second surface 62s is less than 2 μm or less than 1.5 and greater than 0.5 μm or greater than 1 μm. In another embodiment, the amount of the opening 2000, the exposed portion 201p of the first semiconductor layer 201, the first electrode 41, and the first electrode pad 61 may be plural.

The sizes of the light-emitting devices 1 and 1a-1g are not particularly limited. For example, LED chips having the following sizes may be used as light-emitting devices 1 and 1a-1g: a square with a side length of 28 mils (28 mils×28 mils), a square with a side length of 40 mils (40 mils×40 mils), a square with a side length of 46 mils (46 mils×46 mils), a square with a side length of 55 mils (55 mils×55 mils). In addition, the planar shapes of the light-emitting devices 1 and 1a-1g are not limited to the square shape, and a rectangular shape or other shapes may also be adopted. When the planar shapes of the light-emitting devices 1 and 1a-1g are rectangular, for example, an LED chip with a size of 12 mils×50 mils can be adopted as the light-emitting devices 1 and 1a-1g.

The substrate 10 may be a growth substrate for epitaxial growth of the semiconductor stack 200. The substrate 10 includes a gallium arsenide (GaAs) wafer for epitaxial growth of aluminum gallium indium phosphide (AlGaInP), or a sapphire (Al₂O₃) wafer, a gallium nitride (GaN) wafer, a silicon carbide (SiC) wafer, or an aluminum nitride (AlN) wafer for epitaxial growth of gallium nitride (GaN), indium gallium nitride (InGaN) or aluminum gallium nitride (AlGaN).

The upper surface 10t of the substrate 10 connected with the semiconductor stack 200 may be a roughened surface. The roughened surface may be a surface with irregular morphology or a surface with regular morphology. For example, relative to the upper surface 10t of the substrate 10, the substrate 10 includes one or more convex portions (not shown) protruding from the upper surface 10t, or includes one or more concave portions (not shown) recessed on the upper surface 10t. In a cross-sectional view, the convex portions or the concave portions (not shown) may be in the shape of a hemisphere, a cone, a projectile head, or a polygonal cone.

In one embodiment, the convex portions (not shown) of the substrate 10 includes a first layer (not shown) and a second layer (not shown), the first layer includes the same material as that of the substrate 10, such as gallium arsenide (GaAs), sapphire (Al₂O₃), gallium nitride (GaN), silicon carbide (SiC), or aluminum nitride (AlN). The second layer includes a material different than that of the first layer or the substrate 10. The material of the second layer includes an insulating material, such as silicon oxide, silicon nitride, or silicon oxynitride. Viewed from a side surface of the light-emitting device 1, the convex portions (not shown) may be in the shape of a hemisphere, a cone, a projectile head, or a polygonal cone. A top of the convex portion (not shown) may be a flat surface, a curved surface, or a sharp point. In an embodiment of the present disclosure, the convex portion (not shown) includes the second layer without the first layer, wherein a bottom surface of the second layer is flush with the upper surface 10t of the substrate 10.

In one embodiment of the present disclosure, by metal organic chemical vapor deposition (MOCVD), molecular beam epitaxy (MBE), hydride vapor phase epitaxy (HVPE), physical vapor deposition (PVD) wherein the physical vapor deposition includes sputtering or evaporation, or ion plating method, a semiconductor stack 200 with optoelectronic properties, such as a light-emitting stack, is formed on the substrate 10.

The semiconductor stack 200 has a thickness greater than 4 μm and less than 7 μm. The semiconductor stack 200 includes a first semiconductor layer 201, a second semiconductor layer 202, and an active layer 203 formed between the first semiconductor layer 201 and the second semiconductor layer 202. By changing the physical and chemical composition of one or more layers in the semiconductor stack 200, the wavelength of the light emitted by the light-emitting device 1 can be adjusted. The material of the semiconductor stack 200 includes group III-V semiconductor materials, such as AlₓIn_{y}Ga_{(1-x-y)}N or AlₓIn_{y}Ga_{(1-x-y)}P, wherein 0≤x, y≤1. When the material of the semiconductor stack 200 includes AlInGaP series material, the semiconductor stack 200 can emit red light with a wavelength between 610 nm and 650 nm. When the material of the semiconductor stack 200 includes InGaN series material, the semiconductor stack 200 can emit blue light or deep blue light with a wavelength between 400 nm and 490 nm, or green light with a wavelength between 530 nm and 570 nm. When the material of the semiconductor stack 200 includes AlGaN series material or AlInGaN series material, the semiconductor stack 200 can emit ultraviolet light with a wavelength between 250 nm and 400 nm.

The first semiconductor layer 201 and the second semiconductor layer 202 may be a cladding layer or a confinement layer, both of which have different conductivity types, electrical properties, polarities, or dopants that can provide electrons or electron holes. For example, the first semiconductor layer 201 includes n-type semiconductor and the second semiconductor layer 202 includes p-type semiconductor. The active layer 203 is formed between the first semiconductor layer 201 and the second semiconductor layer 202. Electrons and electron holes are driven by an external current to recombine in the active layer 203 so the electrical energy is converted into light energy to emit light. The active layer 203 may be a single heterostructure (SH), a double heterostructure (DH), a double-side double heterostructure (DDH), or a multi-quantum well (MQW) structure. The material of the active layer 203 may be an intrinsic semiconductor, a p-type semiconductor, or an n-type semiconductor. The first semiconductor layer 201, the second semiconductor layer 202, or the active layer 203 may be a single layer or a structure including a plurality of sub-layers.

In one embodiment of the present disclosure, the semiconductor stack 200 may further include a buffer layer (not shown) located between the first semiconductor layer 201 and the substrate 10 to release the stress caused by the lattice mismatch between the substrate 10 and the semiconductor stack 200, and to reduce misalignment and lattice defects, so the epitaxial quality is improved. The buffer layer may be a single layer or a structure including multiple sub-layers. In one embodiment, PVD aluminum nitride (AlN) may be formed as a buffer layer disposed between the semiconductor stack 200 and the substrate 10 to improve the epitaxial quality of the semiconductor stack 200. In one embodiment, a target material for forming PVD aluminum nitride (AlN) is composed of aluminum nitride. In another embodiment, the aluminum nitride is formed by a target material composed of aluminum reacting with a nitrogen source in the environment.

In the light-emitting device 1, a portion of the semiconductor stack 200 is removed by etching the semiconductor stack 200 from the surface until the first semiconductor layer 201 is exposed. In other words, the light-emitting device 1 has the semiconductor platform M and one or more of the exposed portions 201p of the first semiconductor layer 201 formed by etching a portion of the semiconductor stack 200. Therefore, a step difference is formed between the surface of the second semiconductor layer 202 and the exposed portion 201p of the first semiconductor layer 201 in the light-emitting device 1. In the light-emitting device 1, the first electrode 41 is formed on the exposed portion 201p of the first semiconductor layer 201, and the second electrode 40 is formed on the surface of the second semiconductor layer 202. In the light-emitting device 1, when the conductivity type (first conductivity type) of the first semiconductor layer 201 is n-type, and the conductivity type (second conductivity type) of the second semiconductor layer 202 is p-type, the first electrode 41 and the second electrode 40 function as a negative electrode and a positive electrode, respectively. In addition, in the light-emitting device 1, when the first conductivity type is p-type and the second conductivity type is n-type, the first electrode 41 and the second electrode 40 serve as a positive electrode and a negative electrode, respectively.

The shape, size, position, and quantity of the exposed portions 201p of the first semiconductor layer 201 may be appropriately adjusted according to the size, shape or electrode pattern of the light-emitting device 1. As shown in FIG. 2A to FIG. 2C, the exposed portion 201p of the first semiconductor layer may be disposed in a region surrounded by edges of the semiconductor platform M and surrounded by the active layer 203 and the second semiconductor layer 202. A plurality of the exposed portions 201p of the first semiconductor layer 201 is arranged at approximately constant intervals and is separated by the edges of the semiconductor platform M. Accordingly, the luminous area between the adjacent exposed portions 201p of the first semiconductor layer 201 can be kept as large as possible. FIGS. 3A and 3B are top views of the light-emitting devices 1d-1g in accordance with embodiments of the present disclosure. As shown in FIGS. 3A and 3B, the exposed portion 201p of the first semiconductor layer 201 further includes a region extending toward the inside of the light-emitting devices 1d-1e along a direction of a diagonal of the light-emitting devices 1d-1e. FIG. 3C is a top view of the light-emitting device 1f in accordance with an embodiment of the present disclosure. As shown in FIG. 3C, the exposed portion 201p of the first semiconductor layer 201 includes a region extending toward the inside of the light-emitting device 1f along a direction of a diagonal of the light-emitting device 1f, and the exposed portion 201p of the first semiconductor layer 201 further includes a groove portion 201pt recessed toward the inside of the semiconductor platform M from the edge of the semiconductor platform M. Along the side of the light-emitting device 1f, a plurality of the groove portions 201pt of the exposed portion 201p of the first semiconductor layer 201 may be discontinuous. By disposing the grooves 201pt of the exposed portion 201p of the first semiconductor layer 201 on the four edges of the semiconductor platform M and disposing the first electrode 41 thereon, when an external current is injected through the first electrode 41, it can be distributed uniformly even in the region of the edges of the semiconductor platform M. FIG. 3D is a top view of the light-emitting device 1g in accordance with an embodiment of the present disclosure. As shown in FIG. 3D, the groove portions 201pt of the exposed portion 201p of the first semiconductor layer 201 located on the sides of the light-emitting device 1g may be continuous and connected with each other.

As shown in FIG. 2A, the intervals (or the shortest distance) between adjacent exposed portions 201p of the first semiconductor layer 201 may be identical, but not necessarily limited thereto. For example, the intervals between adjacent exposed portions 201p of the first semiconductor layer 201 may be varied according to the wiring patterns on the mounting substrates 20a, 20b and 20c described below. In an embodiment, as shown in FIG. 2B, a first interval D1 between the exposed portions 201p of the first semiconductor layer 201 arranged in a first direction may be less than a second interval D2 between the exposed portions 201p of the first semiconductor layer 201 arranged in a second direction.

In the light-emitting device 1, a surface area of the second semiconductor layer 202 is greater than a total surface area of the exposed portions 201p of the first semiconductor layer 201 to increase the luminous area of the active layer 203. Therefore, in the light-emitting device 1, the size of the area where the second semiconductor layer 202 and the first semiconductor layer 201 overlap in a thickness direction of the first semiconductor layer 201 can be increased to improve luminous efficiency.

The shape of the exposed portion 201p of the first semiconductor layer 201 in the top view includes a circle, an ellipse or a polygon, such as a triangle, a quadrangle, or a hexagon. The size of the exposed portion 201p of the first semiconductor layer 201 may be appropriately adjusted according to the size, output power, or luminance of the light-emitting device 1. The size of the diameter may be from about several tens of micrometers to about several hundreds of micrometers.

All of the exposed portions 201p of the first semiconductor layer 201 may have substantially the same shape and substantially the same size in the top view, each of the exposed portions 201p of the first semiconductor layer 201 may have different shapes and sizes in the top view, or a portion of the exposed portions 201p of the first semiconductor layer 201 may have different shapes and sizes from the other portion of which in the top view. The exposed portions 201p of the first semiconductor layer 201 are located on an area without being covered by the active layer 203, so by regularly arranging and disposing the exposed portions 201p of the first semiconductor layer 201 of the same size, the overall luminance uniformity of the light-emitting device 1 is improved.

As shown in FIG. 1, the light-emitting device 1 includes a passivation layer 30 covering the semiconductor platform M and a portion of the exposed portions 201p of the first semiconductor layer 201. The passivation layer 30 includes one or more first openings 301 and one or more second openings 302. Viewed from the side views of the light-emitting device 1, the first opening 301 of the passivation layer 30 is disposed in the exposed portion 201p of the first semiconductor layer 201 and uncovers the first semiconductor layer 201. The second opening 302 of the passivation layer 30 is disposed on the semiconductor platform M and uncovers the second semiconductor layer 202.

The second electrode 40 is disposed in the second opening 302 of the passivation layer 30 and contacts the second semiconductor layer 202. The second electrode 40 covers an upper surface of the semiconductor platform M. For example, the second electrode 40 may cover more than 80% or 90% of the upper surface of the semiconductor platform M. In an embodiment of the present disclosure, the second electrode 40 may include any one or more layers of a transparent conductive layer 401, a reflective layer 402, and a barrier layer (not shown).

The transparent conductive layer 401 may be disposed between the reflective layer 402 and the second semiconductor layer 202. In another embodiment, another transparent conductive layer (not shown) may be formed between the passivation layer 30 and the second semiconductor layer 202 and extended between the passivation layer 30 and the second semiconductor layer 202. In order to reduce the contact resistance and improve the efficiency of current spreading, the material of the transparent conductive layer 401 includes a material transparent to the light emitted by the active layer 203, such as a transparent conductive oxide. The transparent conductive oxide includes indium tin oxide (ITO) or indium zinc oxide (IZO). In one embodiment of the present disclosure, the transparent conductive layer 401 may be a metal layer with a thickness less than 500 angstroms.

The material of the reflective layer 402 includes a reflective metal, such as aluminum (Al), silver (Ag), rhodium (Rh), platinum (Pt), or an alloy of the previously-mentioned metals. The reflective layer 402 can reflect the light emitted by the active layer 203 so the reflected light can emit outward towards the substrate 10.

In an embodiment of the present disclosure, a barrier layer (not shown) may cover one side of the reflective layer 402 to prevent the reflective layer 402 from being oxidized and deteriorating the reflectivity. The material of the barrier layer includes a metal material, such as titanium (Ti), tungsten (W), aluminum (Al), indium (In), tin (Sn), nickel (Ni), chromium (Cr), platinum (Pt), or an alloy of the previously-mentioned metal materials. In one embodiment, the barrier layer does not cover the reflective layer 402. One side of the barrier layer may be flush with one side of the reflective layer 402, or may be formed on the reflective layer 402 and uncover a portion of the upper surface of the reflective layer 402.

In one embodiment, each of the transparent conductive layer 401, the reflective layer 402 and the barrier layer (not shown) overlaps the passivation layer 30. In other words, the second opening 302 of the passivation layer 30 uncovers the second semiconductor layer 202. The transparent conductive layer 401, the reflective layer 402 and the barrier layer (not shown) are formed in the second opening 302 of the passivation layer 30 and extend upward from the second opening 302 of the passivation layer 30 along the side surface of the passivation layer 30 to cover the upper surface of the passivation layer 30. The side of the reflective layer 402 may be disposed inside or outside of the side of the transparent conductive layer 401, and/or the side of the barrier layer (not shown) may be disposed inside or outside of the side of the reflective layer 402. In other words, an area of the reflective layer 402 may be smaller than an area of the transparent conductive layer 401 and be located within the periphery of the transparent conductive layer 401, or the area of the reflective layer 402 may be larger than the area of the transparent conductive layer 401 and be located outside the periphery of the transparent conductive layer 401. Similarly, the area of the barrier layer may be smaller than the area of the reflective layer 402 and be located within the periphery of the reflective layer 402, or the area of the barrier layer may be larger than the area of the reflective layer 402 and be located outside the periphery of the reflective layer 402. The reflective layer 402 located on the upper surface of the passivation layer 30 includes a sidewall with a slope between 2 and 20 degrees, and the barrier layer (not shown) located on the upper surface of the passivation layer 30 includes a sidewall with a slope between 20 and 60 degrees so that the subsequent insulating layer 50 can evenly cover the barrier layer. The sidewall of the barrier layer has a slope greater than that of the sidewall of the reflective layer. In order to prevent holes in the barrier layer from deteriorating the film quality of the reflective layer 401, the barrier layer has a thickness greater than that of the reflective layer. The barrier layer comprises a thickness greater than 300 nm and less than 1000 nm, or less than 800 nm. The barrier layer includes gold (Au) instead of aluminum (Al) to improve the reliability of the light-emitting device.

The first electrode 41 is located in the exposed portion 201p of the first semiconductor layer 201 and does not cover the semiconductor platform M. In another embodiment, the amount of the first electrode 41 and the exposed portion 201p of the first semiconductor layer 201 may be plural. The external current supplied to the first electrode pad 61 can flow to the first semiconductor layer 201 through the first electrode 41. The second electrode 40 is located on the second semiconductor layer 202 and does not cover one or more the exposed portions 201p of the first semiconductor layer 201. The external current supplied to the second electrode pad 62 can flow to the second semiconductor layer 202 through the second electrode 40. In addition, the first electrode 41 and the second electrode 40 have good light reflectivity and can serve as a reflective layer, so that the light emitted by the active layer 203 and directed towards the first electrode 41 and the second electrode 40 is reflected to the light output surface (namely, one side of the substrate 10).

The first electrode 41 includes a metal material such as chromium (Cr), titanium (Ti), tungsten (W), gold (Au), aluminum (Al), indium (In), tin (Sn), nickel (Ni), platinum (Pt), silver (Ag), or alloys of the previously-mentioned materials. The first electrode 41 may be composed of a single layer or multiple layers, for example, Ti/Au layer, Ti/Pt/Au layer, Cr/Au layer, Cr/Pt/Au layer, Ni/Au layer, Ni/Pt/Au layer, Cr/Al/Cr/Ni/Au layer, or Ag/NiTi/TiW/Pt layer.

When the first electrode 41 and the second electrode 40 are composed of multiple layers, the last layers of the first electrode 41 and the second electrode 40 may include platinum (Pt). The first electrode 41 and the second electrode 40 may serve as a current path for supplying current from an external power source to the first semiconductor layer 201 and the second semiconductor layer 202. Each of the first electrode 41 and the second electrode 40 has a thickness between 1 μm and 10 μm, between 1.5 μm and 5 μm, or between 2.5 μm and 4.5 μm. The first electrode 41 has a thickness greater than or equal to the total thickness of the step difference between the semiconductor platform M and the exposed portion 201p of the first semiconductor layer 201 and the thickness of the second electrode 40. In other words, the first electrode 41 has a thickness greater than that of the second electrode 40.

The insulating layer 50 covering the first electrode 41 and the second electrode 40 includes a first opening 501 exposing the first electrode 41, and a second opening 502 exposing the second electrode 40. The first electrode pad 61 covers the first opening 501 of the insulating layer 50 and contacts the first electrode 41. The second electrode pad 62 covers the second opening 502 of the insulating layer 50 and contacts the second electrode 40.

The passivation layer 30 and/or the insulating layer 50 are disposed on the semiconductor stack 200, and serve as a protective film and an antistatic interlayer insulating film of the light-emitting device 1. As an insulating film, the passivation layer 30 and/or the insulating layer 50 may be a single-layer structure, including metal oxide or metal nitride, and may be selected from oxide, oxynitride, or nitride of the group consisting of silicon (Si), titanium (Ti), zirconium (Zr), Niobium (Nb), tantalum (Ta), and aluminum (Al), for example. The passivation layer 30 and/or the insulating layer 50 may also include two or more materials with different refractive indices stacked alternately to form a distributed Bragg reflector (DBR) structure, which selectively reflects light of a specific wavelength. For example, an insulating reflective structure with high reflectivity may be formed by laminating layers such as SiO₂/TiO₂ or SiO₂/Nb₂O₅. When SiO₂/TiO₂ or SiO₂/Nb₂O₅ forms a distributed Bragg reflector (DBR) structure, each of the layers of the distributed Bragg reflector (DBR) structure is designed to be one or integer multiples of the optical thickness of a quarter of the wavelength of light emitted by the active layer 203. The optical thickness of each of the layers of the distributed Bragg reflector (DBR) structure may have a deviation of ±30% on the basis of one or integer multiples of λ/4. Since the thickness of each of the layers of the distributed Bragg reflector (DBR) structure can affect the reflectivity, E-beam evaporation may be used to form the passivation layer 30 and/or the insulating layer 50 to stably control the thickness of each of the layers of the distributed Bragg reflector (DBR) structure.

In the light-emitting device 1, a size of the second electrode pad 62 may be greater than that of the first electrode pad 61. The second electrode pad 62 may be formed in the central area of the light-emitting device 1, and extend along the periphery of the exposed portions 201p of the first semiconductor layer 201. The second electrode pad 62 includes an area greater than a total area of the plurality of first electrode pads 61, and the second electrode 40 includes an area greater than a total area of the plurality of first electrodes 41. In one embodiment of the present disclosure, the area of the first electrode pad 61 accounts for more than 20%, more than 35%, or more than 50% and less than 65% of the area of the first electrode 41. In one embodiment of the present disclosure, the area of the second electrode pad 62 accounts for more than 20%, more than 35%, or more than 50% and less than 65% of the area of the second electrode 40. In one embodiment of the present disclosure, the area of the second electrode pad 62 is more than 30 times, more than 50 times, or more than 70 times that of the first electrode pad 61. Since the area of the first electrode pad 61 is smaller than that of the second electrode pad 62, in order to avoid affecting the bonding force between the first electrode pad 61, the second electrode pad 62 and the mounting substrate 20a, 20b, 20c described below, resulting in component failure or affecting the service life of the component, the quantity of the first electrode pads 61 may be multiple.

FIG. 2A to FIG. 2C are the top views of light-emitting devices 1a-1c in accordance with embodiments of the present disclosure. FIG. 3A to FIG. 3D are the top views of light-emitting devices 1d-1g in accordance with embodiments of the present disclosure. The shortest vertical distance between the first electrode pad 61 and the second electrode pad 62 is greater than 50 μm and less than 100 μm. The distance between two adjacent first electrode pads 61 is greater than 150 μm and less than 250 μm. First electrode pads 61 illustrated in FIG. 2A to FIG. 2C are separated from each other and have the same size and shape. The plurality of first electrodes 41 and the first electrode pads 61 are symmetrically arranged to improve current distribution. The shape of the first electrode pad 61 in the top view includes a rectangle, a square, a rhombus, or a circle. The shape of the second electrode pad 62 in the top view includes a plurality of concave portions 620 and a plurality of convex portions 621 located on the semiconductor platform M, and each of the concave portions 620 of the second electrode pad 62 includes a radius of curvature greater than the radius or width of the first electrode pad 61. Each of the plurality of first electrode pads 61 is disposed between two adjacent convex portions 621 of the second electrode pad 62. In other words, the first electrode pad 61 is disposed in the concave portion 620 of the second electrode pad 62. The number of the concave portions 620 of the second electrode pad 62 may be less than or equal to the number of the first electrode pads 61. When the number of the concave portions 620 of the second electrode pad 62 is less than the number of the first electrode pads 61, each of the concave portions 620 of the second electrode pad 62 can be configured with one or more of the first electrode pads 61. When the number of the concave portions 620 of the second electrode pad 62 is the same as the number of the first electrode pads 61, the concave portions 620 of the second electrode pad 62 form a one-to-one arrangement with the first electrode pads 61.

In an embodiment of the present disclosure, as shown in each of FIG. 2A to FIG. 2C, an end of the convex portion 621 of the second electrode pad 62 may be closer to the outer edge of each of the light-emitting devices 1a-1c than an end of the first electrode pad 61. A portion or all of the convex portions 621 of the second electrode pad 62 may have different sizes and shapes. Specifically, each of the light-emitting devices 1a-1c includes a first side e1 and a second side e2 connected to each other. The first electrode pad 61 adjacent to the first side e1 and the second side e2 is separated from the first side e1 by a first distance d1 and separated from the second side d2 by a second distance d2, and the second distance d2 is greater than the first distance d1. The second electrode pad 62 is separated from the first side e1 by a first spacing S1 and separated from the second side e2 by a second spacing S2, and the second spacing S2 is less than the second distance d2. The first spacing S1 may be equal to or greater than the second spacing S2.

In one embodiment of the present disclosure, as shown in FIG. 2A to FIG. 2C and FIG. 3A to FIG. 3D, when the shapes of the light-emitting devices 1a-1g are square in the top view, the plurality of first electrode pads 61 may be located on the diagonals of the light-emitting devices 1a-1g, and the numbers of first electrode pads 61 located on different diagonals are the same. The distance between two first electrode pads 61 located on the same diagonal is 1/9 to ½ or ⅙ to ¼ of the length of any of the diagonals. The distance D between two first electrode pads 61 located on the same diagonal is greater than the shortest distance D′ between the first electrode pad 61 and one corner of each of the light-emitting devices 1a-1g.

Compared with the first electrode 41 illustrated in FIG. 2A to FIG. 2C, the first electrode 41 illustrated in FIG. 3A to FIG. 3D has a first bonding electrode 410 and a first extension electrode 411. The first electrodes 41 illustrated in FIG. 3A are separated from each other and have the same size and shape. FIGS. 3B and 3C respectively illustrate that the first electrodes 41 are separated from each other and have similar sizes or shapes. The first electrodes 41 illustrated in FIG. 3D are connected with each other by the first extension electrode 411 to surround the semiconductor platform M.

As shown in FIG. 3B to FIG. 3D, a first diagonal distance between two of the first extension electrodes 411 on the first diagonal is less than a second diagonal distance between two of the first extension electrodes 411 on the second diagonal. Therefore, the distance between two of the concave portions 620 of the second electrode pad 62 on the first diagonal is less than the distance between two of the concave portions 620 of the second electrode pad 62 on the second diagonal.

The second electrode pad 62 illustrated in FIG. 3A includes a symmetrical shape, and includes concave portions 620 to form a one-to-one arrangement with the first extension electrodes 411. The second electrode pad 62 in FIG. 3B to FIG. 3D may include a symmetrical or asymmetrical shape, and include concave portions 620 to form a one-to-one arrangement with the first extension electrodes 411.

As shown in FIGS. 3C and 3D, in the top views of each of the light-emitting devices 1f-1g, the first extension electrodes 411 of the plurality of first electrodes 41 extend along the outer edge of the second electrode 40 and/or the edge of the semiconductor platform M. The first extension electrode 411 located on the first diagonal includes a length L greater than a length L′ included in the first extension sub-electrode 411′ extending from a side of the light-emitting device 1 to the inside of the light-emitting device 1. Specifically, the first extension electrode 411 on the exposed portion 201p of the first semiconductor layer 201 extending toward the inside of the light-emitting device 1 along the diagonal direction of the light-emitting device 1 includes a first length, the first extension sub-electrode 411′ on the groove portion 201pt recessed from an edge of the semiconductor platform M toward the inside of the semiconductor platform M includes a second length, and the first length is greater than the second length.

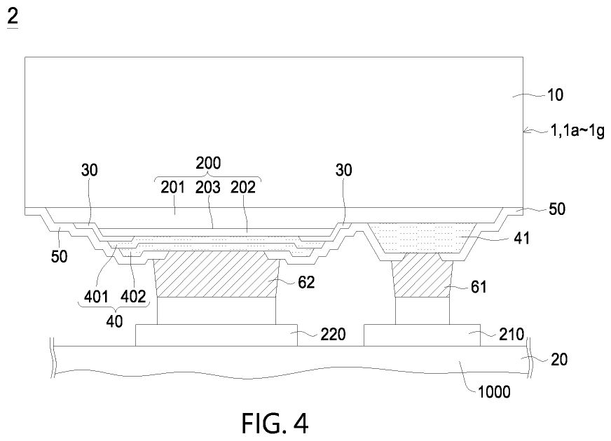

FIG. 4 is a partial cross-sectional view of a light-emitting apparatus 2 in accordance with an embodiment of the present disclosure. In one embodiment of the present disclosure. As shown in FIG. 4, the first electrode pads 61 and the second electrode pad 62 of the light-emitting device 1 are formed on the same side of the semiconductor stack 200 forming a flip chip to be mounted on the mounting substrate 20. The upper surface of the mounting substrate 20 has a wiring pattern, including a first conductor portion 210 and a second conductor portion 220, so that the light-emitting device 1 illustrated in FIG. 1, the light-emitting devices 1a-1c illustrated in FIG. 2A to FIG. 2C, or the light-emitting devices 1d-1g illustrated in FIG. 3A to FIG. 3D are flip-chip mounted on the mounting substrate 20a.

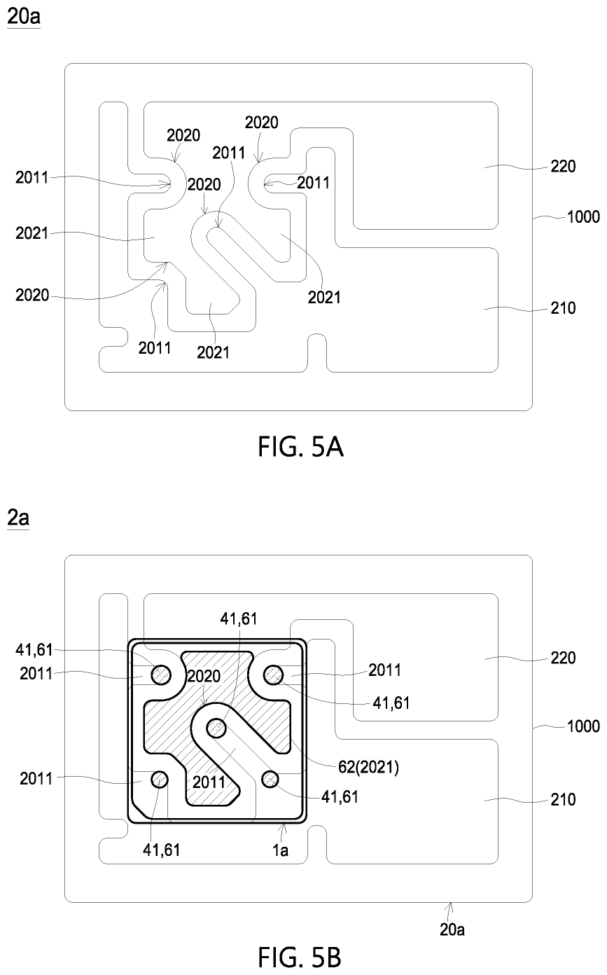

FIG. 5A is a top view of a mounting substrate 20a in accordance with an embodiment of the present disclosure. FIG. 5B is a top view of a light-emitting apparatus 2a in accordance with an embodiment of the present disclosure. Taking the light-emitting device 1a illustrated in FIG. 2A as an example, each of the first conductor portion 210 and the second conductor portion 220 located on the upper surface of the mounting substrate 20a has a wiring pattern corresponding to the patterns of the first electrode pad 61 and the second electrode pad 62 of the light-emitting device 1a, respectively.

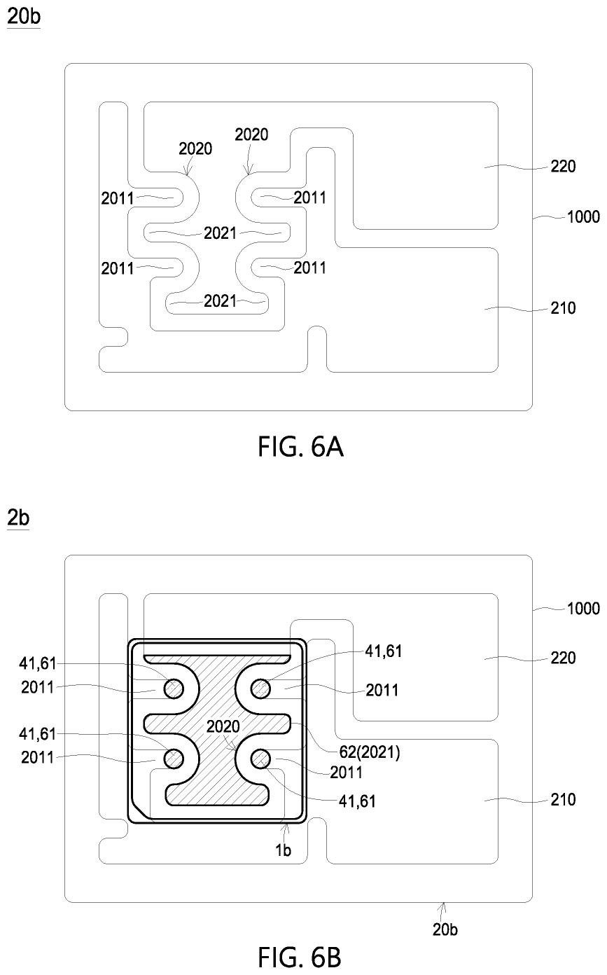

FIG. 6A is a top view of a mounting substrate 20b in accordance with an embodiment of the present disclosure. FIG. 6B is a top view of a light-emitting apparatus 2b in accordance with an embodiment of the present disclosure. Taking the light-emitting device 1b illustrated in FIG. 2B as an example, FIG. 6B illustrates that each of the first conductor portion 210 and the second conductor portion 220 located on the mounting substrate 20b has a wiring pattern corresponding to the patterns of the first electrode pad 61 and the second electrode pad 62 of the light-emitting device 1b, respectively.

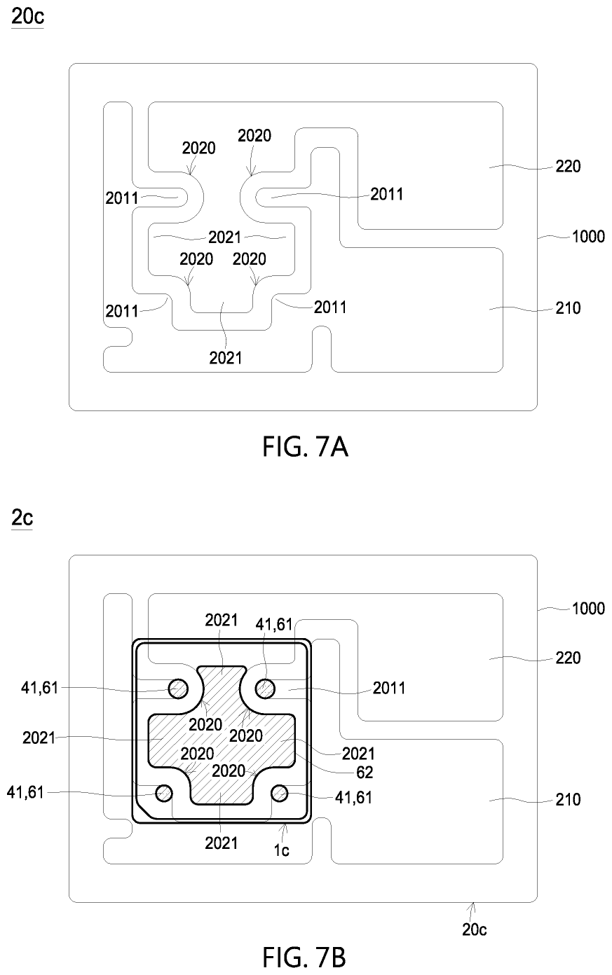

FIG. 7A is a top view of a mounting substrate 20c in accordance with an embodiment of the present disclosure. FIG. 7B is a top view of a light-emitting apparatus 2c in accordance with an embodiment of the present disclosure. Taking the light-emitting device 1c illustrated in FIG. 2C as an example, FIG. 7B illustrates that each of the first conductor portion 210 and the second conductor portion 220 located on the mounting substrate 20c has a wiring pattern corresponding to the patterns of the first electrode pad 61 and the second electrode pad 62 of the light-emitting device 1c, respectively.

Each of the mounting substrates 20a, 20b, 20c includes a first conductor portion 210 and a second conductor portion 220, so that the light-emitting devices 1a, 1b, 1c are in flip-chip form and mounted on the mounting substrates 20a, 20b, 20c, respectively. Each of the mounting substrates 20a, 20b, 20c has a base 1000 to support and to electrically insulate the first conductor portion 210 and the second conductor portion 220. Each of the mounting substrates 20a, 20b, 20c may serve as a heat sink to effectively conduct the heat generated by the light-emitting devices 1a, 1b, 1c to the outside, respectively. For this purpose, the bases 1000 of the mounting substrates 20a, 20b, 20c may be made of a high thermal conductivity material. For example, a material of the base 1000 may include aluminum nitride (AlN), sapphire or silicon carbide (SiC). Alternatively, the base 1000 may have an electrically insulating layer formed on the surface of a silicon substrate, or by forming an electrically insulating layer made of a suitable material on a surface of a metal plate. The material of the metal plate may include a metal exhibiting thermal conductivity. For example, copper (Cu), aluminum (Al), iron (Fe), aluminum (Al) alloy, gold (Au), iron-nickel-cobalt (Fe—Ni—Co) alloy may be the material of the metal plate. For example, SiO₂ or Si₃N₄ may be the material of the electrically insulating layer formed on the surface of the silicon substrate.

As long as the first conductor portion 210 and the second conductor portion 220 can supply current to the light-emitting device 1, the first conductor portion 210 and the second conductor portion 220 may be formed with materials, thicknesses or shapes, which are generally adopted in this industry. Specifically, the first conductor portion 210 and the second conductor portion 220 may be formed of a metal, such as copper (Cu), aluminum (Al), gold (Au), silver (Ag), platinum (Pt), titanium (Ti), tungsten (W), palladium (Pd), iron (Fe), nickel (Ni), or an alloy including the previously-mentioned metals. In particular, in order to efficiently extract the light from the light-emitting device 1, the outermost surfaces of the first conductor portion 210 and the second conductor portion 220 are covered with a material with high reflectivity such as silver or gold. The first conductor portion 210 and the second conductor portion 220 may be formed by electroplating, electroless plating, evaporation deposition, or sputtering. For example, when the outermost surfaces of the first electrode pad 61 and the second electrode pad 62 of the light-emitting device 1 are formed of gold (Au), the outermost surfaces of the first conductor portion 210 and the second conductor portion 220 may be formed of gold (Au) as well. Accordingly, the bondability of the light-emitting devices 1a, 1b, 1c and the mounting substrates 20a, 20b, 20c can be improved, respectively.

The first electrode pad 61 and the second electrode pad 62 in the light-emitting device 1 may be bonded to the first conductor portion 210 and the second conductor portion 220 on the mounting substrates 20a, 20b, 20c by ultrasonic bonding. In addition, the first electrode pad 61 and the second electrode pad 62 may be bonded to the first conductor portion 210 and the second conductor portion 220 on the mounting substrates 20a, 20b, 20c by a bonding member. The bonding member may include a bump, metal powders, metal pastes of resin adhesives, solders, or a low melting point metal, wherein the bump is formed of gold (Au), silver (Ag) or copper (Cu), the metal powders contain such as silver (Ag), gold (Au), copper (Cu), platinum (Pt), aluminum (Al) or palladium (Pd), and the solders contain tin-bismuth, tin-copper, tin-silver or gold-tin.

Each of the first conductor portion 210 and the second conductor portion 220 on the mounting substrate 20a, 20b, 20c has a wiring pattern corresponding to the positions and/or patterns of the first electrode pad 61 and the second electrode pad 62 of the light-emitting devices 1a, 1b, 1c, respectively. Each of the first conductor portions 210 on the mounting substrates 20a, 20b, 20c includes first conductor extensions 2011 corresponding to the first electrode pads 61 on the light-emitting devices 1a, 1b, 1c, respectively. In order to connect with the first electrode pad 61, the first conductor extensions 2011 include different lengths and shapes. Each of the first conductor extensions 2011 includes a portion having a shape identical or similar to a shape of a portion of the first electrode pad 61. A portion of the second conductor portion 220 has a shape identical to that of the second electrode pad 62 to be connected with the second electrode pad 62. The second conductor portion 220 includes concave portions 2020 to respectively accommodate first conductor extensions 2011, and convex portions 2021 disposed corresponding to the convex portions 621 of the second electrode pad 62 illustrated in FIG. 2A to FIG. 2C, respectively. In the top view, the first conductor portion 210 and the second conductor portion 220 have complementary shapes, and the shape of the first conductor portion 210 and the second conductor portion 220 as a whole is similar to a rectangle.

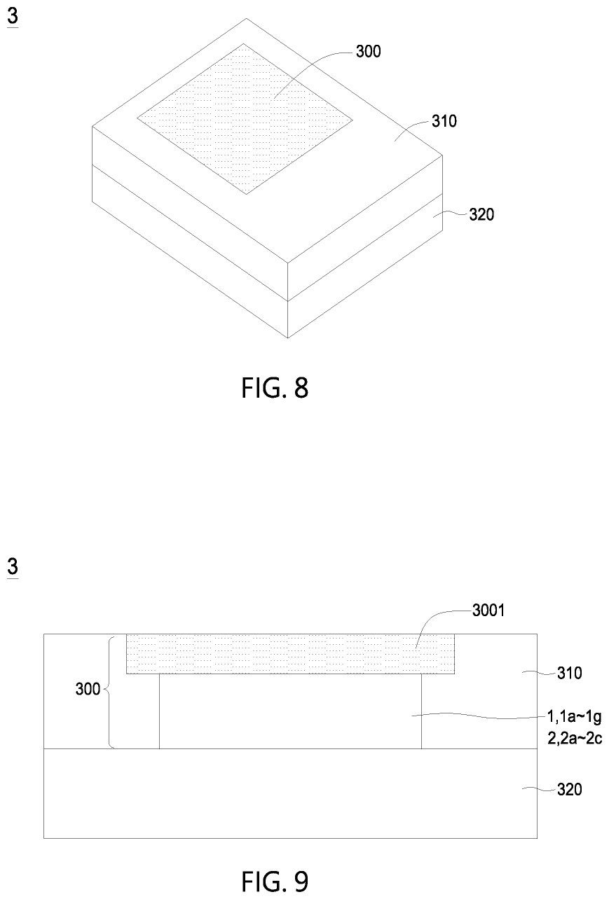

FIG. 8 is a schematic view of a light-emitting apparatus 3 in accordance with an embodiment of the present disclosure. FIG. 9 is a partial cross-sectional view of a light-emitting apparatus 3 in accordance with an embodiment of the present disclosure. The light-emitting apparatus 3 may include one or more light-emitting portions 300. Specifically, the light-emitting apparatus 3 includes the light-emitting portion 300, a side wall portion 310, and a carrier substrate 320, as shown in FIG. 8.

As shown in FIG. 9, the light-emitting portion 300 includes a wavelength converter 3001 and a light-emitting element 3002, wherein the light-emitting element 3002 may be the light-emitting device 1 in FIG. 1, the light-emitting devices 1a-1g in FIG. 2A to FIG. 2C and FIG. 3A to FIG. 3D, the light-emitting apparatus 2 in FIG. 4 or the light-emitting apparatuses 2a-2c in FIGS. 5B, 6B and 7B. The wavelength converter 3001 is formed on the upper portion of the light-emitting element 3002. The wavelength converter 3001 may be formed with a larger area than that of the upper surface of the light-emitting element 3002, or may be formed to cover a side surface of the light-emitting element 3002 (not shown). In another embodiment (not shown), the wavelength converter 3001 may be formed with an area approximately equal to that of the upper surface of the light-emitting element 3002, so that the side surfaces of the light-emitting element 3002 can be formed approximately side by side with the side surfaces of the wavelength converter 3001. In another embodiment (not shown), the wavelength converter 3001 may be formed with an area smaller than that of the upper surface of the light-emitting element 3002, so that the side surfaces of the light-emitting element 3002 protrude from the side surfaces of the wavelength converter 3001.

The wavelength converter 3001 may include various types of phosphors known to those skilled in the art, such as garnet-type phosphors, aluminate phosphors, sulfide phosphors, oxynitride phosphors, nitrogen phosphors, fluoride phosphors, or silicate phosphors, and can convert the wavelength of light emitted from the light-emitting device to emit white light. In one embodiment, when the above-mentioned light-emitting element 3002 releases light with a peak wavelength in the blue light range, the wavelength converter 3001 may include a phosphor which emits light with a peak wavelength longer than that of blue light, for example, green light, red light, or yellow light.

As shown in FIG. 9, the side wall portion 310 may cover the side surfaces of the light-emitting element 3002, or may cover the side surfaces of the wavelength converter 3001 to protect the light-emitting portion 300. In addition, the side wall portion 310 can reflect light. The side wall portion 310 is formed on the outer sides of the light-emitting element 3002 or the outer sides of the wavelength converter 3001, so the light released from the light-emitting portion 300 is concentrated and emits upward, but not limited thereto. The divergence angle of the light emitted from the light-emitting portion 300 may be adjusted according to the reflectivity or light transmittance of the side wall portion 310. The sidewall portion 310 may include an insulating polymer material or ceramics, and may further include a filling material which reflects or scatters light. In addition, the side wall portion 310 may have a function of light transmission, light semi-transmission or light reflectivity. The side wall portion 310 may include a polymer resin, such as silicone resin, epoxy resin, polyimide resin, or polyurethane resin.

As shown in FIG. 9, the carrier substrate 320 may be located at the bottom of the above-mentioned light-emitting element 3002, and can support the light-emitting portion 300 and the side wall portion 310. The carrier substrate 320 may be an insulating substrate or a conductive substrate, and may also be a printed circuit board (PCB) including a conductive pattern. In case that the carrier substrate 320 is an insulating substrate, the carrier substrate 320 may include a polymer material or a ceramic material, for example, a ceramic material having excellent thermal conductivity such as aluminum nitride (AlN).

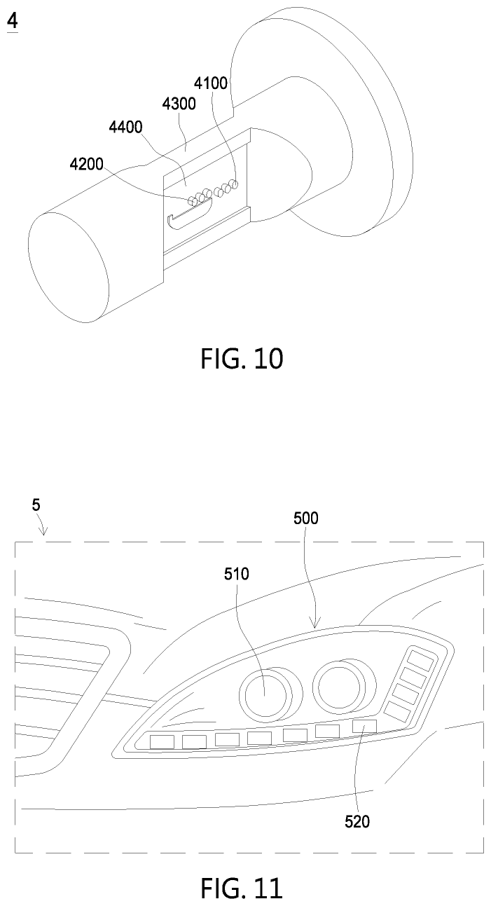

FIG. 10 is a schematic view of a light-emitting apparatus 4 in accordance with an embodiment of the present disclosure. In one embodiment, the light-emitting apparatus 4 is a LED light bulb for a car, which may be plugged and fixed in the mounting through hole on the rear shell of the car headlight assembly. The light-emitting apparatus 4 includes a first LED chip 4100 for low beam light or a second LED chip 4200 for high beam light, a columnar lamp post 4300, a driving power circuit board 4400, cooling fins (not shown), a fan for cooling (not shown), a fan cover (not shown) for shielding the fan, a power cord (not shown) for electrically connecting the vehicle battery, and a plug (not shown) set at the end of the power cord. The first LED chip 4100 or the second LED chip 4200 in the light-emitting apparatus 4 may include any one or more of the above-mentioned light-emitting devices 1, and 1a-1g, light-emitting apparatuses 2 and 2a-2c and light-emitting apparatus 3.

FIG. 11 is a schematic view of a light-emitting apparatus 5 in accordance with an embodiment of the present disclosure. In one embodiment, the light-emitting apparatus 5 may be a car light 500, which may be applied to daytime running lights, headlights, tail lights, or turn signals. The main lighting lamp 510 may be a main light in the car light 500. For example, in the case that the car light 500 is used as a headlight, the main lighting lamp 510 may have the function of illuminating the front headlights of the vehicle. A combination light 520 may have at least two functions. For example, in the case that a car light is used as a headlight, the combination light 520 may perform the functions of a daytime running light (DRL) and a direction indicator. The main lighting lamp 510 or the combination light 520 may include any one or more of the above-mentioned light-emitting devices 1 and 1a-1g, light-emitting apparatuses 2 and 2a-2c, light-emitting apparatus 3 or light-emitting apparatus 4.

Each of the embodiments listed in the present disclosure is merely used to illustrate the present disclosure and is not intended to limit the scope of the present disclosure. Any obvious modifications or variations made by anyone to the present disclosure will not depart from the spirit and scope of the present disclosure.

What is claimed is:

1. A light-emitting device, comprising:
a substrate;
a first semiconductor layer and a semiconductor platform disposed on the first semiconductor layer, wherein the semiconductor platform comprises a second semiconductor layer and an active layer between the first semiconductor layer and the second semiconductor layer;
a plurality of openings passing through the semiconductor platform to uncover the first semiconductor layer;
a plurality of first electrodes located on the first semiconductor layer in the plurality of openings and not covering the semiconductor platform;
a second electrode on the second semiconductor layer and not covering the first semiconductor layer in the plurality of openings;
a plurality of first electrode pads located on the first semiconductor layer in the plurality of openings and not covering the semiconductor platform; and
a second electrode pad located on the semiconductor platform and not covering the first semiconductor layer in the plurality of openings, wherein a first surface of the plurality of first electrode pads is higher than a second surface of the second electrode pad, and a step difference between the first surface and the second surface is less than 2 μm.

2. The light-emitting device according to claim 1, wherein, in a top view, the second electrode pad comprises a plurality of concave portions and a plurality of convex portions on the semiconductor platform.

3. The light-emitting device according to claim 2, wherein each of the plurality of first electrode pads is disposed between two adjacent of the plurality of convex portions of the second electrode pad, and the plurality of first electrode pads corresponds to the plurality of concave portions of the second electrode pad and forms a one-to-one arrangement with the plurality of concave portions of the second electrode pad.

4. The light-emitting device according to claim 2, wherein one of the plurality of first electrode pads and one of the plurality of convex portions of the second electrode pad respectively comprises an end, the light-emitting device comprises an edge, and the end of the one of the plurality of convex portions of the second electrode pad is closer to the edge of the light-emitting device than the end of the one of the plurality of first electrode pads.

5. The light-emitting device according to claim 2, further comprising a first diagonal and a second diagonal, a distance between two of the plurality of concave portions of the second electrode pad on the first diagonal is less than a distance between two of the plurality of concave portions of the second electrode pad on the second diagonal.

6. The light-emitting device according to claim 1, wherein the plurality of first electrode pads has a total area, and the second electrode pad has an area greater than the total area of the plurality of first electrode pads.

7. The light-emitting device according to claim 6, wherein the semiconductor platform has a height, each of the plurality of first electrodes has a thickness greater than the height of the semiconductor platform.

8. The light-emitting device according to claim 1, further comprising an insulating layer covering the plurality of first electrodes and the second electrode, wherein the insulating layer comprises a distributed Bragg reflector (DBR) structure.

9. The light-emitting device according to claim 1, further comprising two diagonals, wherein the plurality of first electrodes is located on one of the two diagonals of the light-emitting device.

10. The light-emitting device according to claim 1, wherein the second electrode comprises an outer edge, each of the plurality of first electrodes comprises a first extension electrode extending along the outer edge of the second electrode in a top view.

11. The light-emitting device according to claim 10, further comprising a first diagonal and a second diagonal, wherein a first diagonal distance between two of the first extension electrodes on the first diagonal is less than a second diagonal distance between two of the first extension electrodes on the second diagonal.

12. The light-emitting device according to claim 1, further comprising a first side and a second side connected with the first side, wherein one of the plurality of first electrode pads adjacent to the first side and the second side is separated from the first side by a first distance and is separated from the second side by a second distance, and the second distance is greater than the first distance.

13. The light-emitting device according to claim 12, wherein the second electrode pad is separated from the first side by a first spacing and separated from the second side by a second spacing, and the second spacing is less than the second distance.

14. The light-emitting device according to claim 13, wherein the first spacing is equal to or greater than the second spacing.

15. The light-emitting device according to claim 1, wherein one of the plurality of first electrode pads and one of the plurality of first electrodes respectively has an area, and the area of the one of the plurality of first electrode pads accounts for a first ratio of that of the one of the plurality of first electrodes, and wherein the second electrode pad and the second electrode respectively has an area, and the area of the second electrode pad accounts for a second ratio of that of the second electrode, wherein the first ratio is greater than the second ratio.

16. A light-emitting apparatus comprising:
a light-emitting device comprising:
a substrate;
a first semiconductor layer and a semiconductor platform disposed on the first semiconductor layer, wherein the semiconductor platform comprises a second semiconductor layer and an active layer between the first semiconductor layer and the second semiconductor layer;
an opening passing through the semiconductor platform to uncover the first semiconductor layer;
a first electrode located on the first semiconductor layer in the opening and not covering the semiconductor platform;
a second electrode on the second semiconductor layer and not covering the first semiconductor layer in the opening;
a first electrode pad located on the first semiconductor layer in the opening and not covering the semiconductor platform, wherein the first electrode pad comprises a first pattern; and
a second electrode pad located on the semiconductor platform and not covering the first semiconductor layer in the opening, wherein the second electrode pad comprises a second pattern, and a first surface of the first electrode pad is higher than a second surface of the second electrode pad; and
a mounting substrate comprising a third pattern and a fourth pattern respectively corresponding to the first pattern and the second pattern of the light-emitting device.

17. The light-emitting apparatus according to claim 16, wherein the mounting substrate further comprises a first conductor portion and a second conductor portion on a surface of the mounting substrate, and the first conductor portion and the second conductor portion respectively comprises the third pattern and the fourth pattern.

18. The light-emitting apparatus according to claim 17, wherein the first conductor portion comprises a first conductor extension and the second conductor portion comprises a first concave portion surrounding the first conductor extension.

19. The light-emitting apparatus according to claim 18, wherein the second electrode pad comprises a second concave portion and a second convex portion on the semiconductor platform, and the second conductor portion comprises a first convex portion corresponding to the second convex portion of the second electrode pad.

20. The light-emitting apparatus according to claim 16, wherein a step difference between the first surface and the second surface is less than 2 μm.
